(19) United States
(12) Patent Application Publication
(10) Pub. No.: US 2005/0093119 A1
(43) Pub. Date: May 5, 2005

(54) Window type case for memory card

(75) Inventors: Wen Chuan Chen, Shinchu Hsien (TW); Kuo-Feng Peng, Shinchu Hsien (TW); Chia Jung Chang, Shinchu Hsien (TW); Chi Hong Chen, Shinchu Hsien (TW)

Correspondence Address: CHARLES C.H. WU, 98 DISCOVERY, IRVINE, CA, 92618-3105, US

(73) Assignee: ABOUNION TECHNOLOGY, CORP.

(21) Appl. No.: 10/698,711

(22) Filed: Oct. 31, 2003

(51) Int. Cl. H01L 23/02

(52) U.S. Cl. 257/678

(57) ABSTRACT

A memory card includes a base plate on which IC chips are connected and a case is mounted to the base plate. At least one window is defined through the case so that at least one of the IC chips is accommodated in the window. A seal plate is attached on the case and seals the at least one window.

### FIELD OF THE INVENTION

The present invention relates to a memory card including a case having a window through which a conventional and thicker IC chips are accommodated.

### BACKGROUND OF THE INVENTION

A conventional memory card 10 is shown in FIGS. 1 and 2 and generally includes a base plate 11 on which various types of IC chips 12 are connected such as Flash chips, or Controller chips. A layer of plastic material 100 is filed in the space between the chips 12 such that the chips 12 are positioned and merged in the plastic material 100. An outer casing 13 is then mounted to the combination of the base 11 and the chips 12. Due to the standard thickness of the memory cards so that the thickness of the IC chips 12 is limited within a small range and this requires special material and machine to make. A high manufacturing cost is expected. Besides, only 0.2 mm to 0.3 mm of thickness is allowed for the outer casing 13 and the thin outer casing is difficult to be manufactured and suffered by high manufacturing cost.

The present invention intends to provide a memory card which includes a case having a window so that a conventional and thicker IC chip is accommodated in the window and a top seal plate is attached to the case to seal the window.

### SUMMARY OF THE INVENTION

In accordance with one aspect of the present invention, there is provided a memory card that comprises a base plate and IC chips are connected to the base plate. A case is mounted to the base plate and at least one window is defined through the case so that at least one of the IC chips is accommodated in the window. A seal plate is attached on the case and seals the at least one window.

The primary object of the present invention is to provide a memory card that employs conventional and thicker IC chips which are accommodated in a window of a case mounted onto the base plate, such that the manufacturing cost can be reduced.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows plastic material is filled in the gaps between the IC chips on the base plate of a conventional memory card;

FIG. 2 is a cross sectional view to show conventional memory card;

FIG. 3 is an exploded view to show the memory card of the present invention;

FIGS. 4 and 5 show two embodiments of the memory card of the present invention.

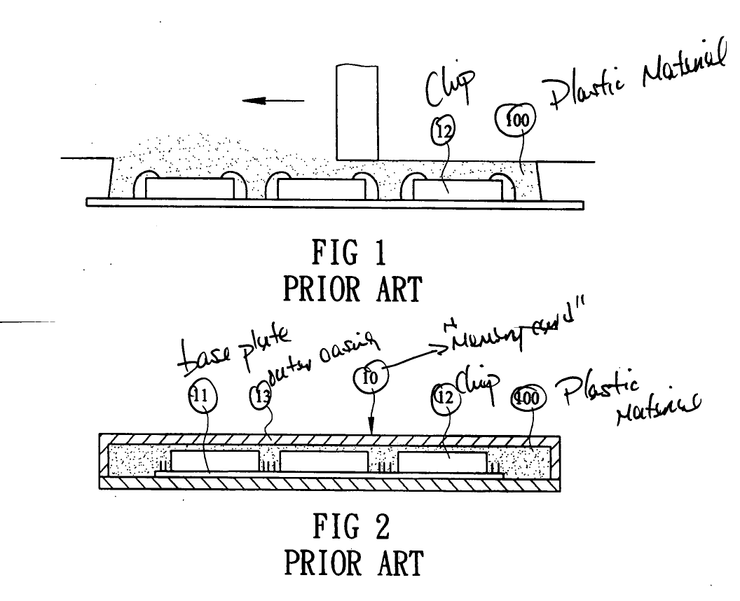

### DETAILED DESCRIPTION OF THE PREFERRED EMBODIMENT

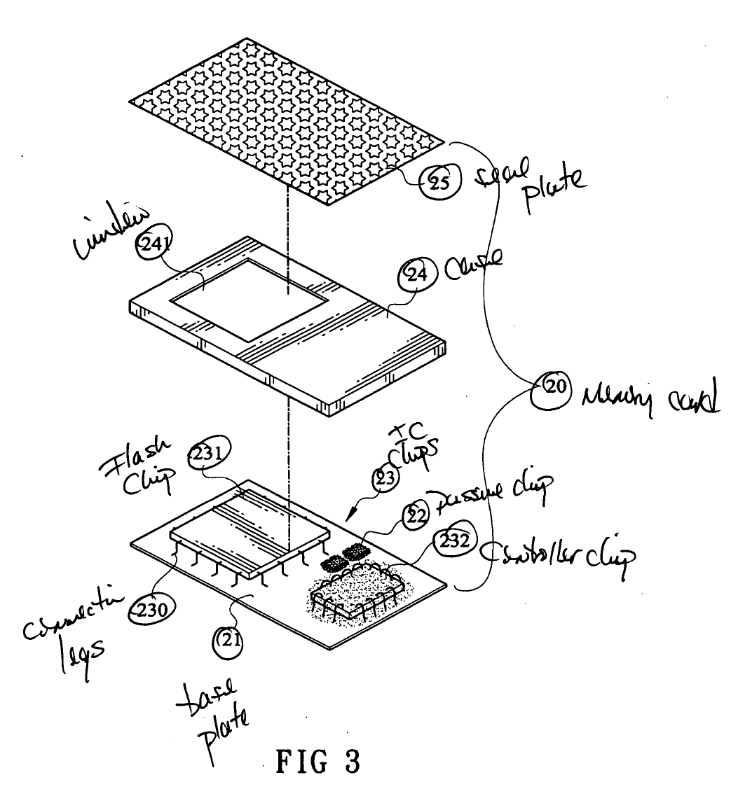

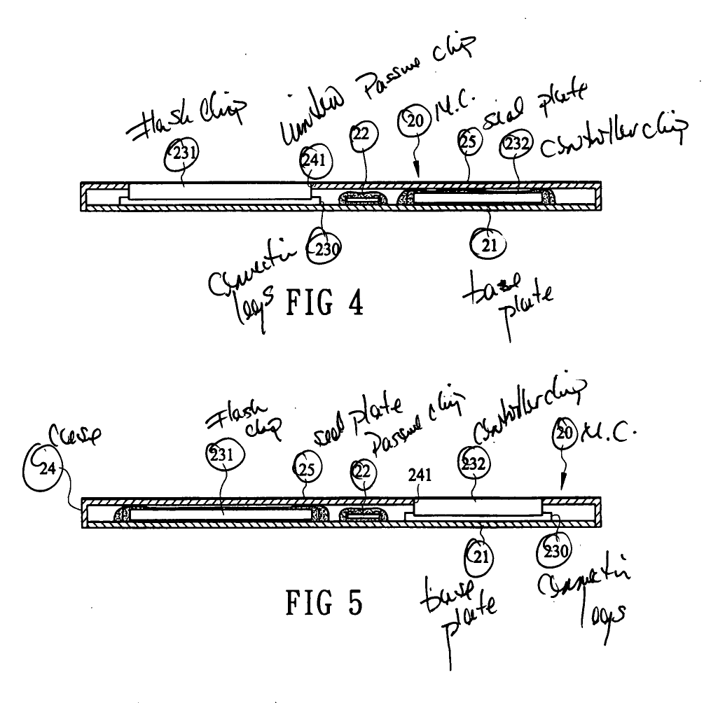

Referring to FIGS. 3 and 4, the memory card 20 of the present invention comprises a base plate 21 on which different types of IC chips 23 such as a Passive chip 22, a Flash chip 231, and a Controller chip 232 are connected. Each of the chips has connection legs 230 electrically connected to the base plate 21 so as to form a circuit board. A case 24 is mounted to the base plate 21 and at least one window 241 is defined through the case 24 so that at least one of the IC chips 23 such as the Flash chip 231 in FIG. 4 or the Controller chip 232 as shown in FIG. 5 is accommodated in the window 241. The top surface of the chips that are accommodated in the at least one window 241 is in flush with the top surface of the case 24. A seal plate 25 is attached on the case 24 and seals the at least one window 241. It is to be noted that necessary processes such as filling the plastic material are proceeded as does to the conventional memory cards.

By the arrangement of the structure of the present invention, the conventional and thicker IC chips can be used and this reduces the manufacturing cost. The standard thickness of the memory card is 1.4 mm with 0.1 mm tolerance, the thickness of the base plate 21 is 0.3 mm, the height between the base plate 21 to an inside of the case 24, and the seal plate 25 is less than 0.1 mm of thickness so that the IC chips 23 are allowed to be 1.1 mm in thickness. This means that conventional and thicker chips can be used in the memory card of the present invention. The thickness of the case 24 can also be reinforced by increasing its thickness to increase the structural strength thereof.

While we have shown and described the embodiment in accordance with the present invention, it should be clear to those skilled in the art that further embodiments may be made without departing from the scope of the present invention.

1. A structure of memory card comprising:
a base plate on which IC chips are connected;
a case mounted to the base plate and at least one window defined through the case so that at least one of the IC chips is accommodated in the at least one window, a space enclosed by the at least one window being larger than the at least one of the IC chips and a top surface of the at least one of the IC chips accommodated in the at least one window being in flush with a top surface of the case, and
a seal plate attached on the case and sealing the at least one window.

2. The device as claimed in claim 1, wherein the IC chips have connection legs electrically connected to the base plate.

3. (canceled)

4. A structure of memory card comprising:
a base plate on which IC chips are connected;
a case mounted to the base plate and at least one window defined through the case so that at least one of the IC chips is accommodated in the at least one window, a space enclosed by the at least one window being slightly larger than the at least one of the IC chips and a top surface of the at least one of the IC chips accommodated in the at least one window being in flush with a tog surface of the case, a periphery of the at least one of the IC chips being fitted and in contact with an inner periphery of the at least one window, and
a seal plate attached on the case and sealing the at least one window.
